(19) United States
(12) Patent Application Publication
(10) Pub. No.: US 2019/0293996 A1
(43) Pub. Date: Sep. 26, 2019

(54) LIQUID CRYSTAL DISPLAY AND MOBILE TERMINAL

(71) Applicant: Huizhou China Star Optoelectronics Technology Co., Ltd., Huizhou City (CN)

(72) Inventor: Bo HAI, Huizhou City (CN)

(21) Appl. No.: 15/989,599

(22) Filed: May 25, 2018

Related U.S. Application Data
(63) Continuation of application No. PCT/CN2018/083307, filed on Apr. 17, 2018.

(30) Foreign Application Priority Data
Mar. 20, 2018 (CN) 201810229791.3

(51) Int. Cl. G02F 1/1335; G02F 1/1362; H01L 27/12; G06F 1/16

(52) U.S. Cl. CPC G02F 1/133528; G06F 1/1637; H01L 27/1214; G02F 1/136286

(57) ABSTRACT

The present disclosure provides a liquid crystal display and a mobile terminal. The liquid crystal display may include: a thin-film transistor (TFT) array substrate; a color film (CF) substrate arranged corresponding to the TFT array substrate; a liquid crystal layer arranged between the TFT array substrate and the CF substrate; a first quarter-wave plate arranged on the TFT array substrate; an upper polarizing plate arranged on the first quarter-wave plate; a lower polarizing plate arranged on the CF substrate, wherein an absorption axis of the lower polarizing plate is substantially perpendicular to an absorption axis of the upper polarizing plate; and a second quarter-wave plate arranged between the lower polarizing plate and the CF substrate, wherein an optical axis of the second quarter-wave plate is substantially perpendicular to an optical axis of the first quarter-wave plate.

### CROSS-REFERENCE TO RELATED APPLICATIONS

The present application is a continuation-application of International (PCT) Patent Application No. PCT/CN2018/083307, field on Apr. 17, 2018, which claims foreign priority of Chinese Patent Application No. 201810229791.3, field on Mar. 20, 2018 in the State Intellectual Property Office of China, the entire contents of which are hereby incorporated by reference.

### TECHNICAL FIELD

The present disclosure generally relates to the liquid crystal display field, and in particular to a liquid crystal display and a mobile terminal.

### BACKGROUND

With the development of the liquid crystal display (LCD) technology, the requirement to the LCD has become higher and higher. At the beginning, users wanted LCDs to be light, thin and stylish. Compared to the liquid crystal display with same size, those slim-bezel or bezel free LCD may provide a wider view of the display image, such that they may seem bigger and have become very popular. Today, high resolution LCDs which have excellent display effect have become a focus of research.

In prior art, as the resolution of LCD increases, the amount of metal wires in the display panel is multiplied. As for those LCDs whose TFT array substrate is arranged to face towards the user, since the metal wires are not covered by the black matrix, the light reflection may also increase. Attaching a circular polarizing plate on the outer side of the upper polarizing plate (the polarizing plate in the TFT array substrate) may effectively reduce the reflection. However, it will also reduce the transmittance.

During research, the applicant of the present disclosure finds that using the current technology for reducing reflection of a high resolution LCD may lead to the problem of reduced transmittance.

### BRIEF DESCRIPTION OF THE DRAWINGS

FIG. 1 is a schematic diagram of a liquid crystal display according to an embodiment of the present disclosure.

FIG. 2 shows the light path of incident light in the LCD of FIG. 1.

FIG. 3 shows the light path of backlight in the LCD of FIG. 1.

FIG. 4 is a schematic diagram of a liquid crystal display according to another embodiment of the present disclosure.

FIG. 5 is a schematic diagram of a liquid crystal display according to yet another embodiment of the present disclosure.

### DETAILED DESCRIPTION

The disclosure will now be described in detail with reference to the accompanying drawings and examples. Apparently, the described embodiments are only a part of the embodiments of the present disclosure, not all of the embodiments. All other embodiments obtained by a person of ordinary skill in the art based on the embodiments of the present invention without creative efforts shall fall within the protection scope of the present invention.

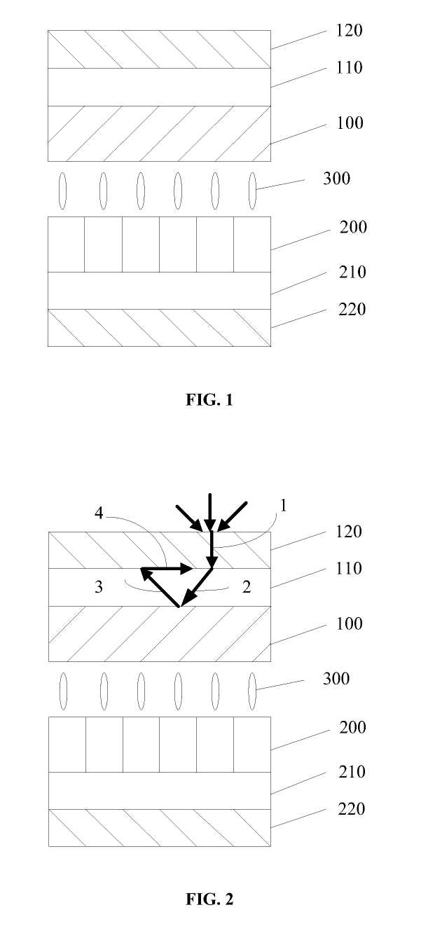

Referring to FIG. 1, FIG. 1 is a schematic diagram of the liquid crystal display according to an embodiment of the present disclosure.

The liquid crystal display (LCD) may include a thin-film transistor (TFT) array substrate 100; a color film (CF) substrate 200 arranged corresponding to the TFT array substrate 100; a liquid crystal layer 300 arranged between the TFT array substrate 100 and the CF substrate 200; a first quarter-wave plate 110 arrange on the TFT array substrate 100; an upper polarizing plate 120 arranged on the first quarter-wave plate 110; a lower polarizing plate 220 arranged on the CF substrate 200, wherein the absorption axis of the lower polarizing plate 220 may be substantially perpendicular to the absorption axis of the upper polarizing plate 120; and a second quarter-wave plate 210 arranged between the lower polarizing plate 220 and the CF substrate 200, wherein the optical axis of the second quarter-wave plate 210 may be substantially perpendicular to the optical axis of the first quarter-wave plate 110.

According to this embodiment, incident light may be converted to a first linearly polarized light after passing through the upper polarizing plate. The first linearly polarized light may be converted to a first circularly polarized light after passing through the first quarter-wave plate. After the first circularly polarized light is reflected from a reflecting surface and passes through again the first quarter-wave plate, it is converted to a linearly polarized light of which the polarization direction is perpendicular to the optical axis of the upper polarizing plate such that reflection can be effectively reduced. Furthermore, the second quarter-wave plate is arranged at a side of the CF substrate far away from the user. Backlight may be converted to a second linearly polarized light after passing through the lower polarizing plate. After the second linearly polarized light passes through the first quarter-wave plate, the liquid crystal layer and the second quarter-wave plate, it is converted to a linearly polarized light of which the polarization direction is perpendicular to the optical direction of the lower polarizing plate. Since the direction of the absorption axis of the upper polarizing plate is substantially perpendicular to that of the lower polarizing plate, the light which has passed through the first quarter-wave plate, the liquid crystal layer and the second quarter-wave plate can completely pass through the upper polarizing plate such that light transmittance is increased. Therefore, the implementation of the present disclosure may reduce incident light reflection and increase backlight transmittance.

In one embodiment, the LCD may be thin film transistor (TFT) LCD. The TFT LCD may have no bezel and have high definition. In this embodiment, the TFT array substrate of the LCD may be arranged to be facing towards the user. Since the size of the TFT array substrate is slightly bigger than that of the CF substrate, the drivers of the scan lines and data lines can be covered by the TFT array substrate so as to realize the bezel-free configuration.

In one embodiment, the first quarter-wave plate may define an optical axis of 45° while the second quarter-wave plate may define an optical axis of 135°. Alternatively, the first quarter-wave plate may define an optical axis of 135° while the second quarter-wave plate may define an optical axis of 45°. In this embodiment, the optical axes of the first quarter-wave plate and the second quarter-wave plate may be perpendicular.

Further, angle deviation of the directions of the optical axes of the first quarter-wave plate and the second quarter-wave plate is tolerable, e.g., the deviation may be ±1°, ±2°, ±3°, ±4° or ±5°.

In one embodiment, the absorption axis of the upper polarizing plate may have a direction of approximately 0° while the absorption axis of the lower polarizing plate may have a direction of approximately 90°. Alternatively, the absorption axis of the upper polarizing plate may have a direction of approximately 90° while the absorption axis of the lower polarizing plate may have a direction of approximately 0°. The absorption axes of the lower polarizing plate and the upper polarizing plate are perpendicular. Thus, the polarization direction of the light which has passed through the lower polarizing plate, the first quarter-wave plate, the liquid crystal layer and the second-wave plate may be perpendicular to the optical axis of the lower polarizing plate, i.e., same as the optical axis of the upper polarizing plate. Thus the light may completely pass through. Therefore, transmittance can be increased and display effect may be improved.

Further, angle deviation of the directions of the absorption axes of the upper polarizing plate and the lower polarizing plate is tolerable, e.g., the deviation may be ±0.2°, ±0.4°, ±0.6°, ±0.8° or ±1°. As long as the deviation is in a certain range and the control of light of the upper polarizing plate and the lower polarizing plate can meet the requirement, the angle deviation of the absorption axes of the upper polarizing plate and the lower polarizing plate is acceptable.

In one embodiment, referring to FIG. 2, FIG. 2 shows the light path of incident light in the LCD of FIG. 1. The direction of the optical axis of the upper polarizing plate 120 may be 90°. The direction of the optical axis of the first quarter-wave plate 110 may be 45°. The direction of the optical axis of the second quarter-wave plate 210 may be 135°. The direction of the optical axis of the lower polarizing plate 220 may be 0°. Incident light may be converted to a linearly polarized light 1 with a polarization direction of 90° after passing through the upper polarizing layer 120 whose optical axis direction is 90°. The linearly polarized light 1 with a polarization direction of 90° may be converted to a first circularly polarized light 2 after passing through the first quarter-wave plate 110 whose optical axis direction is 45°. The first circularly polarized light 2 may be reflected on the metal wires of the TFT array substrate 100 and change into the reflected light 3. After the reflected light 3 passes through the first quarter-wave plate 110, it is converted to a linearly polarized light 4 with a polarization direction of 0°. Thus the linearly polarized light 4 cannot get out from the upper polarizing layer 120. Therefore, the reflection is reduced.

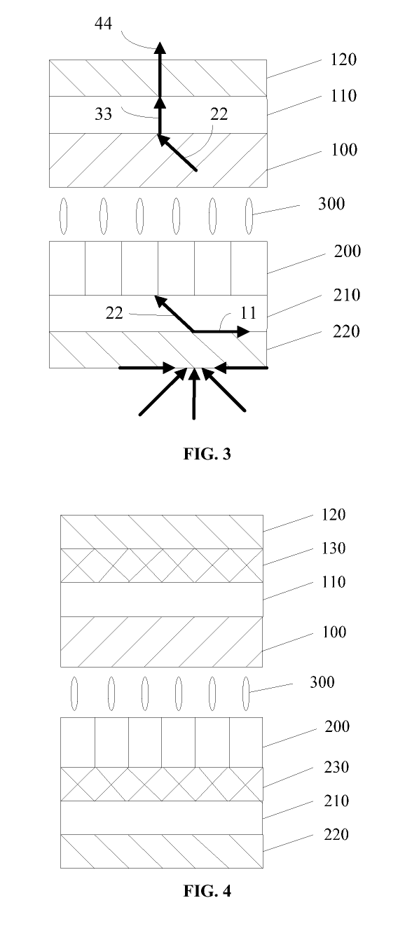

Referring to FIG. 3, FIG. 3 shows the light path of backlight in the LCD of FIG. 1. The direction of the optical axis of the upper polarizing plate 120 may be 90°. The direction of the optical axis of the first quarter-wave plate 110 may be 45°. The direction of the optical axis of the second quarter-wave plate 210 may be 135°. The direction of the optical axis of the lower polarizing plate 220 may be 0°. Backlight may be converted to a linearly polarized light 11 with a polarization direction of 0° after passing through the lower polarized plate 220 whose optical axis direction is 0°. The linearly polarized light 11 with a polarization direction of 0° may be converted to a second circularly polarized light 22 after passing through the second quarter-wave plate 210 whose optical axis direction is 135°. The second circularly polarized light 22 may be converted to the light 33 with a polarization direction of 90° after pass through the liquid crystal layer and the first quarter-wave plate. The polarization direction of the light 33 is the same as the optical axis direction of the upper polarizing plate, thus the light 33 can transmit out completely, which means a high transmittance. According to FIG. 2 and FIG. 3 it can be known that the implementation of the present disclosure may reduce light reflection and increase light transmittance, and thus provide better display effect.

In one embodiment, the TFT array substrate may include metal wires, for example, data lines, scans lines and/or other metal components. The metal wires may be made of aluminum or copper. The aluminum presents silver white. Its light reflectance is greater than 90% in regards to the visible light of any wavelength. Thus it is necessary to design the first quarter-wave plate and the second quarter-wave plate for green light of which the wavelength is between 500 to 600 nm. Since Ro=(Nx−Ny)*d, where Ro is the in-plane phase difference of the quarter-wave plate, Nx and Ny are respectively the refraction indices of the ordinary light and the extraordinary light, and d is the thickness of the quarter-wave plate. The quarter-wave plate corresponding to the aluminum wires should have an in-plane phase difference of 125-150 nm, i.e., the in-plane phase difference of the first quarter-wave plate may be from 125 to 150 nm, and the in-plane phase difference of the second quarter-wave plate may be from 125 to 150 nm. In another embodiment, the first quarter-wave plate and the second quarter-wave plate may be designed according to green light whose wavelength is between 540 to 560 nm. Accordingly, the corresponding quarter-wave plate should have an in-plane phase difference of 135-145 nm, i.e., the in-plane phase difference of the first quarter-wave plate may be from 135 to 145 nm, and the in-plane phase difference of the second quarter-wave plate may be from 135 to 145 nm.

Similarly, since the copper has a low reflectivity for blue light and a high reflectivity for red light and green light, the copper presents yellow. Thus, it is necessary to design the first quarter-wave plate and the second quarter-wave plate for yellow light of which the wavelength is between 550 to 650 nm. Accordingly, the in-plane phase difference of the first quarter-wave plate may be from 137.5 to 162.5 nm, and the in-plane phase difference of the second quarter-wave plate may be from 137.5 to 162.5 nm. In one embodiment, the first quarter-wave plate and the second quarter-wave plate may be designed according to yellow light whose wavelength is between 580 to 600 nm. Accordingly, the corresponding quarter-wave plate should have an in-plane phase difference of 145-150 nm, i.e., the in-plane phase difference of the first quarter-wave plate may be from 145 to 150 nm, and the in-plane phase difference of the second quarter-wave plate may be from 145 to 150 nm.

In one embodiment, the first quarter-wave plate and the second quarter-wave plate may be made of same or different materials. The first quarter-wave plate may include cellulose triacetate and cyclic olefin polymer while the second quarter-wave plate may also include cellulose triacetate and cyclic olefin polymer. In another embodiment, the first quarter-wave plate and the second quarter-wave plate may be made of same materials. The first quarter-wave plate and the second quarter-wave plate may be both made of cyclic olefin polymer. Using the same materials to make the first quarter-wave plate and the second quarter-wave plate may help to control the polarization direction of the circularly polarized light so as to acquire better display effect.

In one embodiment, referring to FIG. 4, FIG. 4 is a schematic diagram of a liquid crystal display according to another embodiment of the present disclosure. The LCD may further include a first compensation layer 130 and/or a second compensation layer 230. The first compensation layer 130 may be arranged between the first quarter-wave plate 110 and the TFT array substrate 100. Alternatively, the first compensation layer 130 may be arranged between the first quarter-wave plate 110 and the upper polarizing plate 120. The second compensation layer 230 may be arranged between the second quarter-wave plate 210 and the CF substrate 200. Alternatively, the second compensation layer 230 may be arranged between the second quarter-wave plate 210 and the lower polarizing plate 220. In other words, the lower polarizing plate 220 and the second quarter-wave plate 210 may be directly connected together or indirectly connected by the second compensation layer 230 therebetween, so long as backlight can pass through the lower polarizing plate 220 before passing through the second quarter-wave plate 210. Similarly, the upper polarizing plate 120 and the first quarter-wave plate 110 may be directly connected together or indirectly connected by the first compensation layer 130 therebetween, so long as incident light can pass through the upper polarizing plate 120 before passing through the second quarter-wave plate 120.

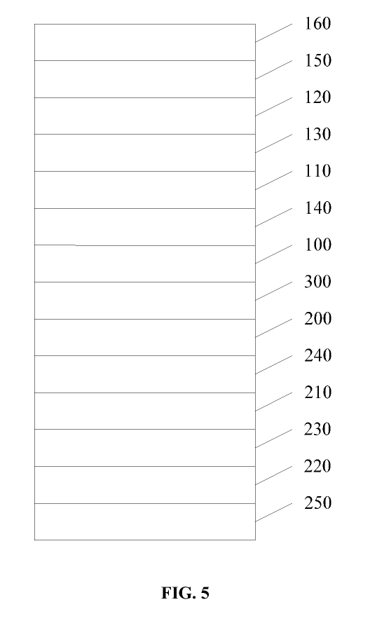

In another embodiment, referring to FIG. 5, FIG. 5 is a schematic diagram of a liquid crystal display according to yet another embodiment of the present disclosure. The LCD may include: a TFT array substrate 100; a color film (CF) substrate 200 arranged corresponding to the TFT array substrate 100; a liquid crystal layer 300 arranged between the TFT array substrate 100 and the CF substrate 200; a first PSA (pressure sensitive adhesive) layer 140, a first quarter-wave plate 110, a first compensation layer 130, an upper polarizing plate 120, a first protection layer 150 and an AG (anti-glare) surface layer 160 successively disposed on the TFT array substrate 100; a second PSA layer 240, a second quarter-wave plate 210, a second compensation layer 230, a lower polarizing layer 220 and a second protection layer 250 successively disposed on the CT substrate 200. The first protection layer 150 may be disposed at a side of the upper polarizing plate 120 far away from the TFT array substrate 100. The second protection layer 250 may be disposed at a side of the lower polarizing plate 220 far away from the CF substrate 200. The arrangement of the first protection layer 150, the second protection layer 250 and the AG surface layer 160 may improve the display effect of the LCD and avoid the influence of moisture and dust to the LCD. Thus the performance of the LCD may be improved and its service life may be extended.

In conclusion, the present disclosure provides a liquid crystal display. The liquid crystal display includes: a thin-film transistor (TFT) array substrate; a color film (CF) substrate arranged corresponding to the TFT array substrate; a liquid crystal layer arranged between the TFT array substrate and the CF substrate; a first quarter-wave plate arranged on the TFT array substrate; an upper polarizing plate arranged on the first quarter-wave plate; a lower polarizing plate arranged on the CF substrate, wherein an absorption axis of the lower polarizing plate is substantially perpendicular to an absorption axis of the upper polarizing plate; and a second quarter-wave plate arranged between the lower polarizing plate and the CF substrate, wherein an optical axis of the second quarter-wave plate is substantially perpendicular to an optical axis of the first quarter-wave plate.

To solve the above mentioned problem, another technical scheme adopted by the present disclosure is to provide a mobile terminal. The mobile terminal may include a liquid crystal display. The liquid crystal display may include a thin-film transistor (TFT) array substrate; a color film (CF) substrate arranged corresponding to the TFT array substrate; a liquid crystal layer arranged between the TFT array substrate and the CF substrate; a first quarter-wave plate arranged on the TFT array substrate; an upper polarizing plate arranged on the first quarter-wave plate; a lower polarizing plate arranged on the CF substrate, wherein an absorption axis of the lower polarizing plate may be substantially perpendicular to an absorption axis of the upper polarizing plate; and a second quarter-wave plate arranged between the lower polarizing plate and the CF substrate, wherein an optical axis of the second quarter-wave plate may be substantially perpendicular to an optical axis of the first quarter-wave plate; wherein, the TFT array substrate may include a metal wire, and the metal wire may include aluminum or copper; wherein the first quarter-wave plate may include cellulose triacetate and cyclic olefin polymer, and the second quarter-wave plate may include cellulose triacetate and cyclic olefin polymer.

The foregoing is merely embodiments of the present disclosure, and is not intended to limit the scope of the disclosure. Any transformation of equivalent structure or equivalent process which uses the specification and the accompanying drawings of the present disclosure, or directly or indirectly application in other related technical fields, are likewise included within the scope of the protection of the present disclosure.

What is claimed is:

1. A liquid crystal display, comprising:
a thin-film transistor (TFT) array substrate;
a color film (CF) substrate corresponding to the TFT array substrate;
a liquid crystal layer disposed between the TFT array substrate and the CF substrate;
a first quarter-wave plate arranged on the TFT array substrate;
an upper polarizing plate arranged on the first quarter-wave plate;
a second quarter-wave plate arranged on the CF substrate, wherein an optical axis of the second quarter-wave plate is substantially perpendicular to an optical axis of the first quarter-wave plate;
a lower polarizing plate arranged on second quarter-wave plate, wherein an absorption axis of the lower polarizing plate is substantially perpendicular to an absorption axis of the upper polarizing plate; and
wherein a first angle between the optical axis of the first quarter-wave plate and the absorption axis of the upper polarizing plate is approximately 45°, and a second angle between the optical axis of the second quarter-wave plate and the absorption axis of the lower polarizing plate is approximately 45°.

2. The liquid crystal display of claim 1, wherein the first quarter-wave plate and the second quarter-wave plate comprise the same materials.

3. The liquid crystal display of claim 2, wherein the first and second quarter-wave plates comprise cellulose triacetate and cyclic olefin polymer.

4. The liquid crystal display of claim 1, wherein the TFT array substrate comprises an aluminum metal wire, and an in-plane phase difference of the first quarter-wave plate is from 125 nm to 150 nm, and an in-plane phase difference of the second quarter-wave plate is from 125 nm to 150 nm.

5. The liquid crystal display of claim 4, wherein the in-plane phase difference of the first quarter-wave plate is from 135 nm to 145 nm, and the in-plane phase difference of the second quarter-wave plate is from 135 nm to 145 nm.

6. The liquid crystal display of claim 1, wherein the TFT array substrate comprises a metal wire, and the metal wire is made of copper, an in-plane phase difference of the first quarter-wave plate is from 137.5 nm to 162.5 nm, and an in-plane phase difference of the second quarter-wave plate is from 137.5 nm to 162.5 nm.

7. The liquid crystal display of claim 6, wherein the in-plane phase difference of the first quarter-wave plate is from 145 nm to 150 nm, and the in-plane phase difference of the second quarter-wave plate is from 145 nm to 150 nm.

8. The liquid crystal display of claim 1, further comprising at least one of a first compensation layer and a second compensation layer, wherein the first compensation layer is arranged between the first quarter-wave plate and the TFT array substrate or between the first quarter-wave plate and the upper polarizing plate, wherein the second compensation layer is arranged between the second quarter-wave plate and the CF substrate or between the second quarter-wave plate and the lower polarizing plate.

9. The liquid crystal display of claim 1, further comprising:
a first protection layer arranged at a side of the upper polarizing plate far away from the TFT array substrate;
a second protection layer arranged at a side of the lower polarizing plate far away from the CF substrate.

10. A liquid crystal display, comprising:
a thin-film transistor (TFT) array substrate;
a color film (CF) substrate corresponding to the TFT array substrate;
a liquid crystal layer disposed between the TFT array substrate and the CF substrate;
a first quarter-wave plate arranged on the TFT array substrate;
an upper polarizing plate arranged on the first quarter-wave plate;
a second quarter-wave plate arranged on the CF substrate, wherein an optical axis of the second quarter-wave plate is substantially perpendicular to an optical axis of the first quarter-wave plate; and
a lower polarizing plate arranged on the second quarter-wave plate, wherein an absorption axis of the lower polarizing plate is substantially perpendicular to an absorption axis of the upper polarizing plate.

11. The liquid crystal display of claim 10, wherein the first quarter-wave plate defines an optical axis of approximately 45°, and the second quarter-wave plate correspondingly defines an optical axis of approximately 135°; or the first quarter-wave plate defines an optical axis of approximately 135°, and the second quarter-wave plate correspondingly defines an optical axis of approximately 45°.

12. The liquid crystal display of claim 11, wherein the absorption axis of the upper polarizing plate has a direction of approximately 0°, and the absorption axis of the lower polarizing plate correspondingly has a direction of approximately 90°; or the absorption axis of the upper polarizing plate has a direction of approximately 90°, and the absorption axis of the lower polarizing plate correspondingly has a direction of approximately 0°.

13. The liquid crystal display of claim 10, wherein the TFT array substrate comprises a metal wire, and the metal wire comprises aluminum or copper.

14. The liquid crystal display of claim 10, wherein an in-plane phase difference of the first quarter-wave plate is from 125 nm to 150 nm, an in-plane phase difference of the second quarter-wave plate is from 125 nm to 150 nm; or an in-plane phase difference of the first quarter-wave plate is from 137.5 nm to 162.5 nm, an in-plane phase difference of the second quarter-wave plate is from 137.5 nm to 162.5 nm.

15. The liquid crystal display of claim 14, wherein the in-plane phase difference of the first quarter-wave plate is from 135 nm to 145 nm, the in-plane phase difference of the second quarter-wave plate is from 135 nm to 145 nm; or the in-plane phase difference of the first quarter-wave plate is from 145 nm to 150 nm, the in-plane phase difference of the second quarter-wave plate is from 145 nm to 150 nm.

16. The liquid crystal display of claim 10, wherein the first quarter-wave plate and the second quarter-wave plate comprise the same materials.

17. The liquid crystal display of claim 10, wherein the first and the second quarter-wave plates comprise cellulose triacetate and cyclic olefin polymer.

18. The liquid crystal display of claim 10, further comprising a first compensation layer and/or a second compensation layer, wherein the first compensation layer is arranged between the first quarter-wave plate and the TFT array substrate or between the first quarter-wave plate and the upper polarizing plate, wherein the second compensation layer is arranged between the second quarter-wave plate and the CF substrate or between the second quarter-wave plate and the lower polarizing plate.

19. The liquid crystal display of claim 10, further comprising:
a first protection layer arranged at a side of the upper polarizing plate far away from the TFT array substrate;
a second protection layer arranged at a side of the lower polarizing plate far away from the CF substrate.

20. A mobile terminal with a liquid crystal display, wherein the liquid crystal display comprises:
a thin-film transistor (TFT) array substrate;
a color film (CF) substrate corresponding to the TFT array substrate;
a liquid crystal layer disposed between the TFT array substrate and the CF substrate;
a first quarter-wave plate arranged on the TFT array substrate;
an upper polarizing plate arranged on the first quarter-wave plate;
a second quarter-wave plate arranged on the CF substrate, wherein an optical axis of the second quarter-wave plate is substantially perpendicular to an optical axis of the first quarter-wave plate;
a lower polarizing plate arranged on the second quarter-wave plate, wherein an absorption axis of the lower polarizing plate is substantially perpendicular to an absorption axis of the upper polarizing plate; and
wherein, the TFT array substrate comprises a metal wire, and the metal wire comprises aluminum or copper;
wherein the first and the second quarter-wave plates comprise cellulose triacetate and cyclic olefin polymer.
